(19) United States
(12) Patent Application Publication
(10) Pub. No.: US 2023/0070571 A1
(43) Pub. Date: Mar. 9, 2023

(54) Intelligent Peak Detection Method Under Physical Phenomenon

(71) Applicant: Halliburton Energy Services, Inc., Houston, TX (US)

(72) Inventors: Tingting Zeng, Houston, TX (US); Ketan Chimanlal Bhaidasna, Houston, TX (US)

(73) Assignee: Halliburton Energy Services, Inc., Houston, TX (US)

(21) Appl. No.: 17/468,322

(22) Filed: Sep. 7, 2021

(51) Int. Cl. E21B 45/00; G06F 17/14; G01R 23/16

(52) U.S. Cl. CPC E21B 45/00; G06F 17/142; G01R 23/16

(57) ABSTRACT

A method for downhole measurement operations. The method may include taking one or more measurements with a sensor disposed in a bottom hole assembly, converting the one or more measurements into one or more revolutions-per-minute (RPM) measurements, identifying one or more frequency components of the one or more RPM measurements using a Fast Fourier Transform, identifying one or more peaks of the one or more frequency components, and identifying torsional oscillation based at least in part on the one or more peaks. The method may be performed on a non-transitory computer-readable tangible medium comprising executable instructions that cause a computer device to take one or more signal measurements, identify one or more frequency components of the one or more signal measurements using a Fast Fourier Transform, and identify one or more peaks of the one or more frequency components.

### BACKGROUND

In order to obtain hydrocarbons such as oil and gas, boreholes are drilled through hydrocarbon-bearing subsurface formations. During drilling operations, directionally drilling operations may by performed where the drilling direction may veer of an intended drilling path at an angle or even horizontally away from the drilling path. During directional drilling, many sensors may take one or more measurements of drill bit rotation as well as rotation of a bottom hole assembly. Analyzing the measurements and frequency components of the measurements may allow personal to understand the efficiency of the drill bit and bottom hole assembly during directional drilling operations. Specifically, analyzing peaks within a signal may allow for the determination of current functionality of the drill bit or bottom hole assembly.

Detecting peaks from a signal is a challenging operation. In practice, signals are usually interrupted by noise. Another typical physical phenomenon occurs in practice is that a signal often contains overlapped peaks. Yet, peak detection with the existence of noise has been investigated with vast effort, a computational-effective method to locate a dominant peak from a group of overlapped ones is still missing.

### BRIEF DESCRIPTION OF THE DRAWINGS

These drawings illustrate certain aspects of some examples of the present disclosure and should not be used to limit or define the disclosure.

FIG. 1 illustrate an example of a drilling system;

FIG. 2 is a schematic view of an information handling system;

FIG. 3 is another schematic view of the information handling system;

FIG. 4 is a workflow for peak detection in a drilling operation;

FIG. 5 is a graph illustrating different points of a signal;

FIG. 6 is a graph illustrating one or more local maxima and/or one or more local minima;

FIG. 7 is a graph illustrating an interpolation of the signal; and

FIG. 8 is a workflow for peak detection.

### DETAILED DESCRIPTION

Described below are methods and systems for analyzing signal measurements taken of a rotary steerable system (“RSS”) during drilling operations. However, the methods and systems described below may be utilized for any downhole tool or signal processing application. Methods and systems described below may allow for automation to detect dominant peaks from a noisy signal with consideration to possible overlapping peaks.

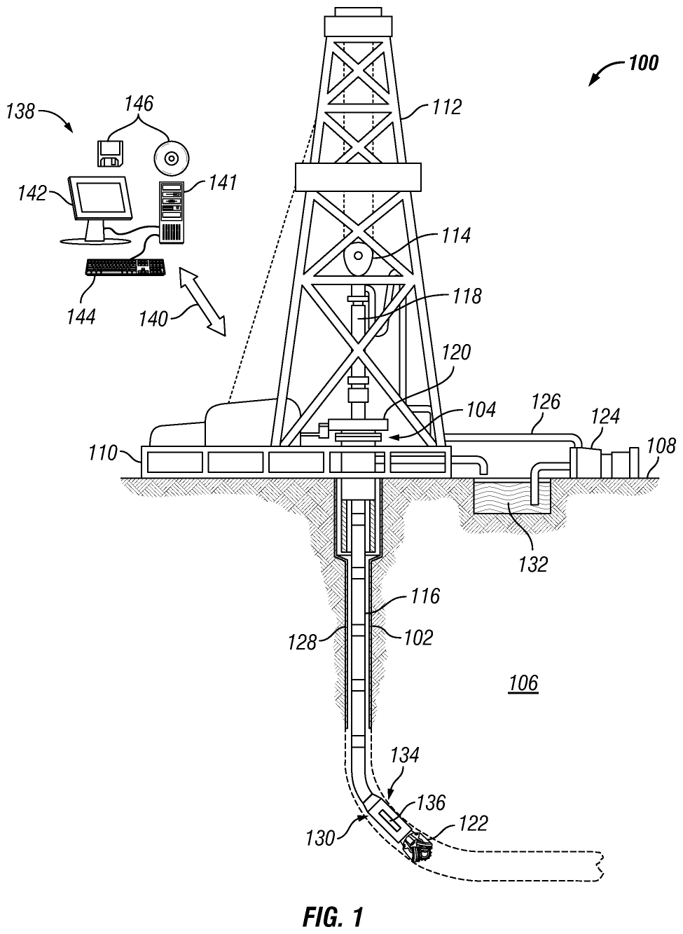

FIG. 1 illustrates a drilling system 100 in accordance with example embodiments. As illustrated, borehole 102 may extend from a wellhead 104 into a subterranean formation 106 from a surface 108. Generally, borehole 102 may include horizontal, vertical, slanted, curved, and other types of borehole geometries and orientations. Borehole 102 may be cased or uncased. In examples, borehole 102 may include a metallic member. By way of example, the metallic member may be a casing, liner, tubing, or other elongated steel tubular disposed in borehole 102.

As illustrated, borehole 102 may extend through subterranean formation 106. As illustrated in FIG. 1, borehole 102 may extend generally vertically into the subterranean formation 106, however borehole 102 may extend at an angle through subterranean formation 106, such as horizontal and slanted boreholes. For example, although FIG. 1 illustrates a vertical or low inclination angle well, high inclination angle or horizontal placement of the well and equipment may be possible. It should further be noted that while FIG. 1 generally depict land-based operations, those skilled in the art may recognize that the principles described herein are equally applicable to subsea operations that employ floating or sea-based platforms and rigs, without departing from the scope of the disclosure.

As illustrated, a drilling platform 110 may support a derrick 112 having a traveling block 114 for raising and lowering drill string 116. Drill string 116 may include, but is not limited to, drill pipe and coiled tubing, as generally known to those skilled in the art. A kelly 118 may support drill string 116 as it may be lowered through a rotary table 120. A drill bit 122 may be attached to the distal end of drill string 116 and may be driven either by a downhole motor and/or via rotation of drill string 116 from surface 108. Without limitation, drill bit 122 may include, roller cone bits, PDC bits, natural diamond bits, any hole openers, reamers, coring bits, and the like. As drill bit 122 rotates, it may create and extend borehole 102 that penetrates various subterranean formations 106. A pump 124 may circulate drilling fluid through a feed pipe 126 through kelly 118, downhole through interior of drill string 116, through orifices in drill bit 122, back to surface 108 via annulus 128 surrounding drill string 116, and into a retention pit 132.

With continued reference to FIG. 1, drill string 116 may begin at wellhead 104 and may traverse borehole 102. Drill bit 122 may be attached to a distal end of drill string 116 and may be driven, for example, either by a downhole motor and/or via rotation of drill string 116 from surface 108. Drill bit 122 may be a part of a rotary steerable tool (RSS) 130 at distal end of drill string 116. RSS 130 may further include tools for real-time health assessment of a rotary steerable tool during drilling operations. As will be appreciated by those of ordinary skill in the art, RSS 130 may be a measurement-while drilling (MWD) or logging-while-drilling (LWD) system.

RSS 130 may comprise any number of tools, such as sensors, transmitters, and/or receivers to perform downhole measurement operations or to perform real-time health assessment of a rotary steerable tool during drilling operations. For example, as illustrated in FIG. 1, RSS 130 may be included on and/or with a bottom hole assembly (BHA) 134. It should be noted that BHA 134 may make up at least a part of RSS 130. Without limitation, any number of different measurement assemblies, communication assemblies, battery assemblies, and/or the like may form RSS 130 with BHA 134. Additionally, BHA 134 may form RSS 130 itself. In examples, BHA 134 may comprise one or more sensors 136. Sensors 136 may be connected to information handling system 138, discussed below, which may further control the operation of sensors 136. Sensors 136 may include (accelerometers, magnetometers, temperature sensors, speed, position sensors, etc.). During operations, sensors 136 may process real time data originating from various sources such as diagnostics data, sensor measurements, operational data, survey measurements, sensory state, drilling system 100 state, BHA 134 state, RSS 130 state, and/or the like. Information and/or measurements may be processed further by information handling system 138 to determine real time heal assessment of rotary steerable tool.

Without limitation, RSS 130 may be connected to and/or controlled by information handling system 138, which may be disposed on surface 108. Without limitation, information handling system 138 may be disposed downhole in RSS 130. Processing of information recorded may occur downhole and/or on surface 108. Processing occurring downhole may be transmitted to surface 108 to be recorded, observed, and/or further analyzed. Additionally, information recorded on information handling system 138 that may be disposed downhole may be stored until RSS 130 may be brought to surface 108. In examples, information handling system 138 may communicate with RSS 130 through a communication line (not illustrated) disposed in (or on) drill string 116. In examples, wireless communication may be used to transmit information back and forth between information handling system 138 and RSS 130. Information handling system 138 may transmit information to RSS 130 and may receive as well as process information recorded by RSS 130. In examples, a downhole information handling system (not illustrated) may include, without limitation, a microprocessor or other suitable circuitry, for estimating, receiving and processing signals from RSS 130. Downhole information handling system (not illustrated) may further include additional components, such as memory, input/output devices, interfaces, and the like. In examples, while not illustrated, RSS 130 may include one or more additional components, such as analog-to-digital converter, filter and amplifier, among others, that may be used to process the measurements of RSS 130 before they may be transmitted to surface 108. Alternatively, raw measurements from RSS 130 may be transmitted to surface 108.

Any suitable technique may be used for transmitting signals from RSS 130 to surface 108, including, but not limited to, wired pipe telemetry, mud-pulse telemetry, acoustic telemetry, and electromagnetic telemetry. While not illustrated, RSS 130 may include a telemetry subassembly that may transmit telemetry data to surface 108. At surface 108, pressure transducers (not shown) may convert the pressure signal into electrical signals for a digitizer (not illustrated). The digitizer may supply a digital form of the telemetry signals to information handling system 138 via a communication link 140, which may be a wired or wireless link. The telemetry data may be analyzed and processed by information handling system 138.

As illustrated, communication link 140 (which may be wired or wireless, for example) may be provided that may transmit data from RSS 130 to an information handling system 138 at surface 108. Information handling system 138 may include a personal computer 141, a video display 142, a keyboard 144 (i.e., other input devices), and/or non-transitory computer-readable media 146 (e.g., optical disks, magnetic disks) that can store code representative of the methods described herein. In addition to, or in place of processing at surface 108, processing may occur downhole as information handling system 138 may be disposed on RSS 130. Likewise, information handling system 138 may process measurements taken by one or more sensors 136 automatically or send information from sensors 136 to the surface. As discussed above, the software, algorithms, and modeling are performed by information handling system 138. Information handling system 138 may perform steps, run software, perform calculations, and/or the like automatically, through automation (such as through artificial intelligence (“AI”), dynamically, in real-time, and/or substantially in real-time.

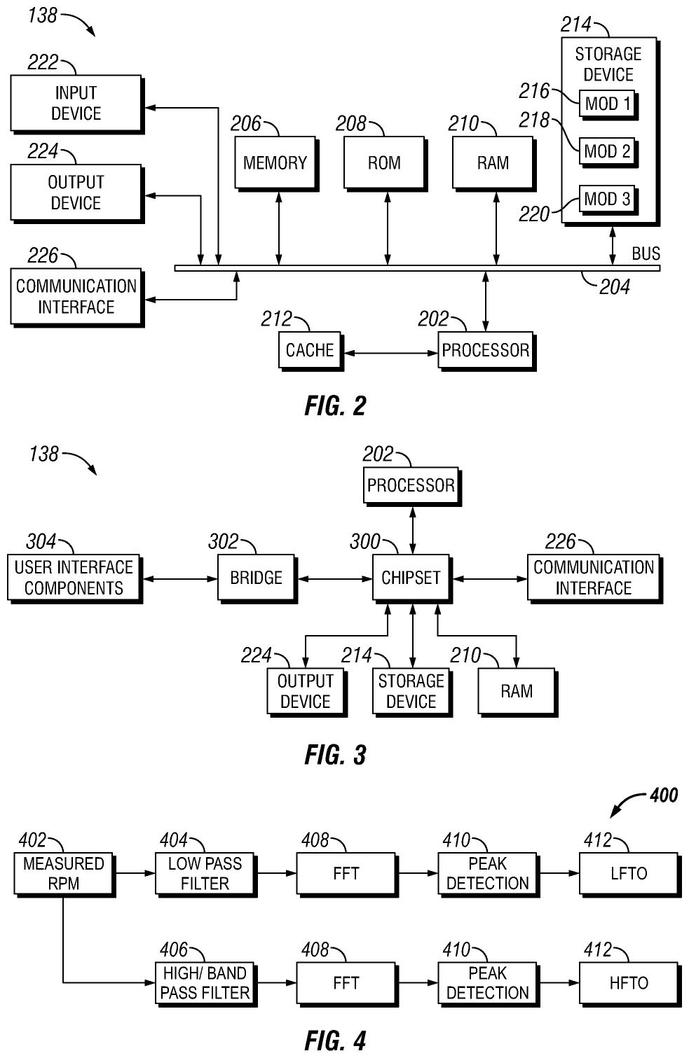

FIG. 2 illustrates an example information handling system 138 which may be employed to perform various steps, methods, and techniques disclosed herein. Persons of ordinary skill in the art will readily appreciate that other system examples are possible. As illustrated, information handling system 138 includes a processing unit (CPU or processor) 202 and a system bus 204 that couples various system components including system memory 206 such as read only memory (ROM) 208 and random access memory (RAM) 210 to processor 202. Processors disclosed herein may all be forms of this processor 202. Information handling system 138 may include a cache 212 of high-speed memory connected directly with, in close proximity to, or integrated as part of processor 202. Information handling system 138 copies data from memory 206 and/or storage device 214 to cache 212 for quick access by processor 202. In this way, cache 212 provides a performance boost that avoids processor 202 delays while waiting for data. These and other modules may control or be configured to control processor 202 to perform various operations or actions. Other system memory 206 may be available for use as well. Memory 206 may include multiple different types of memory with different performance characteristics. It may be appreciated that the disclosure may operate on information handling system 138 with more than one processor 202 or on a group or cluster of computing devices networked together to provide greater processing capability. Processor 202 may include any general purpose processor and a hardware module or software module, such as first module 216, second module 218, and third module 220 stored in storage device 214, configured to control processor 202 as well as a special-purpose processor where software instructions are incorporated into processor 202. Processor 202 may be a self-contained computing system, containing multiple cores or processors, a bus, memory controller, cache, etc. A multi-core processor may be symmetric or asymmetric. Processor 202 may include multiple processors, such as a system having multiple, physically separate processors in different sockets, or a system having multiple processor cores on a single physical chip. Similarly, processor 202 may include multiple distributed processors located in multiple separate computing devices but working together such as via a communications network. Multiple processors or processor cores may share resources such as memory 206 or cache 212 or may operate using independent resources. Processor 202 may include one or more state machines, an application specific integrated circuit (ASIC), or a programmable gate array (PGA) including a field PGA (FPGA).

Each individual component discussed above may be coupled to system bus 204, which may connect each and every individual component to each other. System bus 204 may be any of several types of bus structures including a memory bus or memory controller, a peripheral bus, and a local bus using any of a variety of bus architectures. A basic input/output (BIOS) stored in ROM 208 or the like, may provide the basic routine that helps to transfer information between elements within information handling system 138, such as during start-up. Information handling system 138 further includes storage devices 214 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 214 may include software modules 216, 218, and 220 for controlling processor 202. Information handling system 138 may include other hardware or software modules. Storage device 214 is connected to the system bus 204 by a drive interface. The drives and the associated computer-readable storage devices provide nonvolatile storage of computer-readable instructions, data structures, program modules and other data for information handling system 138. In one aspect, a hardware module that performs a particular function includes the software component stored in a tangible computer-readable storage device in connection with the necessary hardware components, such as processor 202, system bus 204, and so forth, to carry out a particular function. In another aspect, the system may use a processor and computer-readable storage device to store instructions which, when executed by the processor, cause the processor to perform operations, a method or other specific actions. The basic components and appropriate variations may be modified depending on the type of device, such as whether information handling system 138 is a small, handheld computing device, a desktop computer, or a computer server. When processor 202 executes instructions to perform “operations”, processor 202 may perform the operations directly and/or facilitate, direct, or cooperate with another device or component to perform the operations.

As illustrated, information handling system 138 employs storage device 214, which may be a hard disk or other types of computer-readable storage devices which may store data that are accessible by a computer, such as magnetic cassettes, flash memory cards, digital versatile disks (DVDs), cartridges, random access memories (RAMs) 210, read only memory (ROM) 208, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 138, an input device 222 represents any number of input mechanisms, such as a microphone for speech, a touch-sensitive screen for gesture or graphical input, keyboard, mouse, motion input, speech and so forth. Additionally, input device 222 may take in data from one or more sensors 136, discussed above. An output device 224 may also be one or more of a number of output mechanisms known to those of skill in the art. In some instances, multimodal systems enable a user to provide multiple types of input to communicate with information handling system 138. Communications interface 226 generally governs and manages the user input and system output. There is no restriction on operating on any particular hardware arrangement and therefore the basic hardware depicted may easily be substituted for improved hardware or firmware arrangements as they are developed.

As illustrated, each individual component describe above is depicted and disclosed as individual functional blocks. The functions these blocks represent may be provided through the use of either shared or dedicated hardware, including, but not limited to, hardware capable of executing software and hardware, such as a processor 202, that is purpose-built to operate as an equivalent to software executing on a general purpose processor. For example, the functions of one or more processors presented in FIG. 2 may be provided by a single shared processor or multiple processors. (Use of the term “processor” should not be construed to refer exclusively to hardware capable of executing software.) Illustrative embodiments may include microprocessor and/or digital signal processor (DSP) hardware, read-only memory (ROM) 208 for storing software performing the operations described below, and random-access memory (RAM) 210 for storing results. Very large-scale integration (VLSI) hardware embodiments, as well as custom VLSI circuitry in combination with a general-purpose DSP circuit, may also be provided.

The logical operations of the various methods, described below, are implemented as: (1) a sequence of computer implemented steps, operations, or procedures running on a programmable circuit within a general use computer, (2) a sequence of computer implemented steps, operations, or procedures running on a specific-use programmable circuit; and/or (3) interconnected machine modules or program engines within the programmable circuits. Information handling system 138 may practice all or part of the recited methods, may be a part of the recited systems, and/or may operate according to instructions in the recited tangible computer-readable storage devices. Such logical operations may be implemented as modules configured to control processor 202 to perform particular functions according to the programming of software modules 216, 218, and 220.

In examples, one or more parts of the example information handling system 138, up to and including the entire information handling system 138, may be virtualized. For example, a virtual processor may be a software object that executes according to a particular instruction set, even when a physical processor of the same type as the virtual processor is unavailable. A virtualization layer or a virtual “host” may enable virtualized components of one or more different computing devices or device types by translating virtualized operations to actual operations. Ultimately however, virtualized hardware of every type is implemented or executed by some underlying physical hardware. Thus, a virtualization compute layer may operate on top of a physical compute layer. The virtualization compute layer may include one or more virtual machines, an overlay network, a hypervisor, virtual switching, and any other virtualization application.

FIG. 3 illustrates an example information handling system 138 having a chipset architecture that may be used in executing the described method and generating and displaying a graphical user interface (GUI). Information handling system 138 is an example of computer hardware, software, and firmware that may be used to implement the disclosed technology. Information handling system 138 may include a processor 202, representative of any number of physically and/or logically distinct resources capable of executing software, firmware, and hardware configured to perform identified computations. Processor 202 may communicate with a chipset 300 that may control input to and output from processor 202. In this example, chipset 300 outputs information to output device 224, such as a display, and may read and write information to storage device 214, which may include, for example, magnetic media, and solid-state media. Chipset 300 may also read data from and write data to RAM 210. A bridge 302 for interfacing with a variety of user interface components 304 may be provided for interfacing with chipset 300. Such user interface components 304 may include a keyboard, a microphone, touch detection and processing circuitry, a pointing device, such as a mouse, and so on. In general, inputs to information handling system 138 may come from any of a variety of sources, machine generated and/or human generated.

Chipset 300 may also interface with one or more communication interfaces 226 that may have different physical interfaces. Such communication interfaces may include interfaces for wired and wireless local area networks, for broadband wireless networks, as well as personal area networks. Some applications of the methods for generating, displaying, and using the GUI disclosed herein may include receiving ordered datasets over the physical interface or be generated by the machine itself by processor 202 analyzing data stored in storage device 214 or RAM 210. Further, information handling system 138 receive inputs from a user via user interface components 304 and execute appropriate functions, such as browsing functions by interpreting these inputs using processor 202.

In examples, information handling system 138 may also include tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

During drilling operations information handling system 138 may process different types of the real time data originated from varied sampling rates and various sources, such as diagnostics data, sensor measurements, operations data, and or the like through one or more sensors 136 disposed at any suitable location within and/or on RSS 130. (e.g., referring to FIG. 1). These measurements from one or more sensors 136 may allow for information handling system 138 to perform real-time assessment of operations and functionality of RSS 130.

During operations the movement of RSS 130 may be utilized to perform a real-time assessment of downhole operations. For example, one or more sensors 136 may be utilized to take bit wobble measurements, revolutions-per-minute (RPM) measurements, and/or stick slip measurements. Each of these measurements may provide information to an operator in real-time on how RSS 130 is performing downhole during drilling operations. Although not illustrated, a gyroscope may be disposed in RSS 130 to take may on these measurements as one of the sensors 136. Gyroscope measurements may comprise, but are not limited to, measurements of angular velocity about at least two axes. The angular velocity may be measured during the drilling, for example, while rotating RSS 130 to advance drill bit 22. As noted above, the angular velocity may be obtained using gyroscope disposed in in RSS 130 in a known positional relationship. Gyroscope measurements may include measurements of angular velocity (pitch rate, roll rate, yaw rate) about the x-, y-, and z-axes of the gyroscope. Each measurement separately and/or concurrently may identify how RSS 130 may react upon drilling into different formations 106 during drilling operations.

Revolutions-per-minute (RPM) are derived from measurements taken by a gyroscope. RPMs may be utilized in many ways to determine real-time functionality and operational ability of RSS 130. To accurately determine what RSS 130 may be experiencing, such as stick slip, wobble, and/or the like, peaks are identified in measurements taken by the gyroscope. Detecting peaks from a signal is a common task encountered in various industry fields. In practice, signals are usually interrupted by noise. Another typical physical phenomenon occurs in practice is that a signal often contains overlapped peaks. Yet peak detection with the existence of noise has been investigated with vast effort, a computational-effective method to locate a dominant peak from a group of overlapped ones is still missing.

FIG. 4 illustrates a workflow 400 for peak detection in a drilling operation. Workflow 400 may begin with block 402 in which RPM is measured by a gyroscope in RSS 130. RPM measurements provide instantaneous RPM of RSS 130 as it is rotating to cut formation rock. In examples, a mud motor and/or the like may rotate RSS 130 at the same and constant RPM over significant lengths of time. As noted above, RPM may be derived from gyroscope measurements. Gyroscope measurements may derive RPM as gyroscope measurements provide instantaneous angular velocity in radians/sec as seen below:

$$ω = \frac{2 π N}{60} \qquad ( 1 )$$

$$N = 60 \frac{ω}{2 π} \qquad ( 2 )$$

where ω=angular velocity in rad./sec and N=Revolutions/min.

While RPM may be set as a constant by mechanisms of surface motor and/or flow, in reality it is not constant at RSS 130. RSS 130 RPM may vary based on bit-rock interaction, fundamental resonance of drill string and RPM, torque, and/or weight on bit (WOB). Such a phenomenon is defined as stick slip or torsional vibration. Generally, the stick slip frequencies may be low in frequency ranging from 0 to 10 Hz. In addition to low frequency stick slip, RSS 130 may experience high frequency torsional oscillations in the range of 40 to 500 Hz. After measuring RPM in block 402, RPM measurements may be passed through low band pass filter in block 404 or high band pass filter in block 406. The determination of block 404 or block 406 depends on if measurements encounter low frequency stick slip of high frequency oscillation, discussed above.

After passing through suitable filtering in block 404 or block 406, a fast Fourier transform (FFT) is applied in block 408 to convert time domain signal to frequency domain to ascertain the frequency components of the torsional oscillations. From block 408, three frequency components which may have the highest amplitude may be found in block 410 in which peak detection is performed. However, only identifying three peaks of the highest amplitude may result in incorrect frequency reporting, if the amplitude were to lie on the skirt of the highest amplitude. Due to telemetry limitations in transferring data to surface and limitations in computing/storage capacity downhole electronics, only significant frequencies are derived using computationally inexpensive algorithm.

To perform a suitable peak detection in block 410, the following methods are disclosed. The measured signal (such as derived from a gyroscope to determine RPM) may be analyzed to find a local minima and maxima in the signal. The local maxima and minima for a signal are usually found through the 1^{st} order derivative of such signal as below. For a discrete signal f(k) with length N, the following equation is derived:

f′(k):=f(k+1)−f(k), k=1,2,3, . . . N−1 (3)

as the 1^{st} order derivative of f(k), or f′ in short.
Let a local maximum be the point k—such that,

f′(k−1)>0&f′(k)<0. (4)

Similarly, let a local minimum be the point k—such that,

f′(k−1)<0&f′(k)>0. (5)

In addition, the first entry of the signal is considered as a local minimum if f′ (1)>0 and the last entry of the signal is considered to as a local minimum of f′(N−1)<0, respectively. Thus, calculating the 1st order derivative of the signal as f, as described above, may allow personnel to find all the local maxima as P={P₁, P₂, . . . }, and local minima as B={B₁, B₂, . . . }.

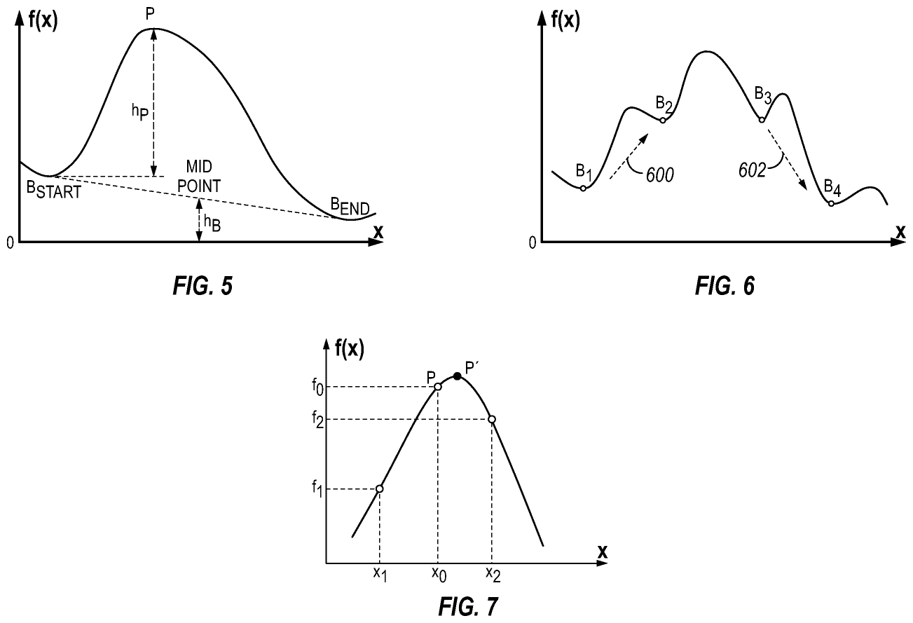

With Reference to FIG. 5, which is a graph illustrating a hypothetical signal, a mathematical measure to quantify the shape of a peak may be expressed as:

$$α ( P ) := \frac{{h}_{P}}{{h}_{B}} \qquad ( 6 )$$

where h_{P} denotes the peak's height, which is the height of the local maximum P, and h_{B} denotes the baseline's height with starting point Bₛₜₐᵣₜ and ending point B_{end}, which is the average height of the local minima Bₛₜₐᵣₜ and B_{end}.

A local maximum P that satisfies the following:

α(P)>α₀ (7)

are identifies as a qualified peak from the noisy signal, where α₀ is a user-defined threshold.

Many data acquisition and processing systems exhibit effects of spectral leakage around the primary Peak. This is due to limitations in sampling of Processing in bins such as Fast Fourier Transforms (FFT). To overcome the challenge of overlapped peaks in a signal, an ascending baseline 600 and descending baseline 602 is utilized, as illustrated in FIG. 6. An ascending baseline is defined as a case in which:

f(Bₛₜₐᵣₜ)≤f(B_{end}) (8)

as noted by B₁ and B₂. Similarly, a descending baseline is defined as a case in which:

f(Bₛₜₐᵣₜ)>f(B_{end}) (9)

as noted by B₃ and B₄.

FIG. 7 is a graph illustrating an interpolation for a given a set of discrete data points. As illustrated, a curve is constructed passing through those data points and the curve may predict values of the curve at other points. Quadratic interpolation may improve the identification and precision of each peak's location. It should be noted that other interpolation techniques such as Gaussian Interpolation may also be employed. As illustrated in FIG. 7, where P is one dominant peak found from the signal, a fitted parabola is computed and is used to predict the location of the parabola's peak P′. The data points being fitted as, the dominant peak P found from the signal, (x₀, y₀), and the two closest points from the signal, (x₁, f₁) and (x₂, f₂). Thus, the parabola takes the form of:

f=ax²+bx+c (10)

Substituting the three data points into this curve, coefficients of the polynomial may be solved and create:

$$( \begin{matrix}a \\ b \\ c\end{matrix} ) = {( \begin{matrix}{x}_{0}^{2} & {x}_{0} & 1 \\ {x}_{1}^{2} & {x}_{1} & 1 \\ {x}_{2}^{2} & {x}_{2} & 1\end{matrix} )}^{- 1} ( \begin{matrix}{f}_{0} \\ {f}_{1} \\ {f}_{2}\end{matrix} ) \qquad ( 11 )$$

Referring back to FIG. 4, in block 412 low frequency torsional oscillations and high frequency torsional oscillations are found from the peak detection found in block 410.

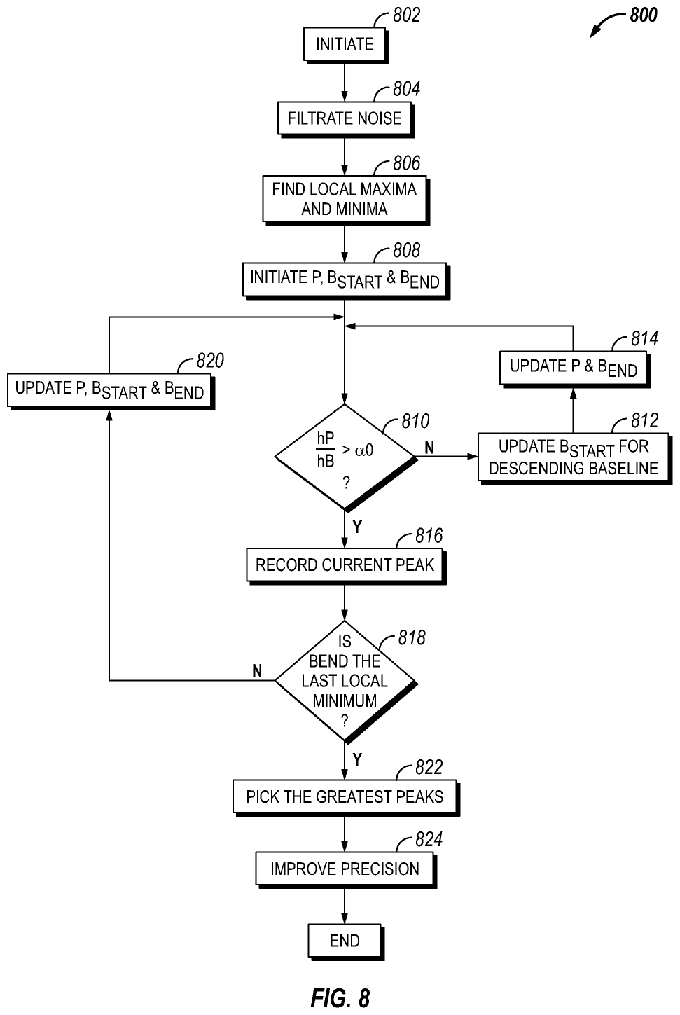

FIG. 8 illustrates a workflow 800 for peak detection. Workflow 800 may begin with block 802 in which one or more measurements are initiated. Such measurements should be discrete, finite, and one dimensional. For example, discrete-time measurement from a sensor, discrete signal waveform, spectrum data, etc. Some examples of signals that would require peak detection when it comes to drilling activity are to quantify peak amplitude of time series accelerometer signal in a z-direction when compared to its average amplitude. Such a quantification may be used to quantify a vibration mode call “bit bounce” in case of stick slip. Additionally, time domain RPM signal is converted to the Frequency domain to ascertain the variation in RPM. This may allow for personnel to identify the most dominant frequency modes by finding the peak Frequency in wideband varying signal. During the initiate step, a number of peak need to be found Nₚₑₐₖ, the noise cutoff threshold wo, and the peak shape threshold α₀ are defined by personnel. This is done based on the experience of the personnel and focusing processing on a specific area of a measured signal. From one or more measurements taken in block 802, a noise filter in block 802 is applied to the one or more measurements. For example, one or more measurements may be passed through a low band pass filter or a high band pass filter to form a filtered measurement. Additionally, in block 802, one or more measurements may be filtered by a band-stop filter to reject frequencies in a certain band, which is useful when prior knowledge such as no peak exists over the stopband is available.

The filtered measurement in block 804 may then be analyzed in block 806 to find local maxima, P={P₁, P₂, . . . } and minima, B={B₁, B₂, . . . }. Local maxima or minima may be found using the methods described above in block 410, referring to FIG. 4, using Equations (3)-(5). After identifying a maxima and a minima in block 806, in block 808 a height of the local maximum P, starting point Bₛₜₐᵣₜ, and ending point B_{end} are found in block 808. At the beginning of the loop, initiate with P=P₁, Bₛₜₐᵣₜ=B₁ and B_{end}=B₂. It should be noted that B₁<P₁ holds true by default due to the property of a Fast Fourier Transform (FFT). In block 810, Equation (6) uses the peak's height h_{P}, which is the height of the local maximum P, and baseline's height h_{B} to determine if a ratio is greater than the threshold α₀. If Equation (6) is solved and the result is not greater than α₀, then workflow 800 moves to block 812, which updates Bₛₜₐᵣₜ for a descending baseline, and does not update Bₛₜₐᵣₜ for ascending baseline. This is performed when, referring to FIGS. 5 and 6, current {Bₛₜₐᵣₜ=Bⱼ, B_{end}=Bₖ} form a descending baseline, then update Bₛₜₐᵣₜ with the upcoming Bⱼ₊₁ otherwise Bₛₜₐᵣₜ=Bⱼ is kept. After block 812, both P and B_{end} are updated in block 814. This is performed by an update that utilizes {P=Pᵢ₊₁, B_{end}=Bₖ₊₁}.

After updates in blocks 812 and 814 are preformed, the mathematical operation in block 810 is performed again to determine if the result is greater than α₀. If the result is greater than α₀ workflow 800 moves to block 816, which records the peak identified in block 810 as DP={P=Pᵢ, Bₛₜₐᵣₜ=Bⱼ, B_{end}=Bₖ, h_{P}, h_{B}}, which represents the local maximum P, the starting point Bₛₜₐᵣₜ, the ending point B_{end}, the peak's height h_{P}, and the baseline's height h_{B}. After recording operations are performed in block 816, the B_{end} is reviewed to determine if it is that last local minimum in block 818. This operation is performed by searching local minima B={B₁, B₂, . . . }. If B_{end} is not the last local minimum, workflow 800 moves to block 820, which updates P, Bₛₜₐᵣₜ, and B_{end} as follows, {P=Pᵢ₊₁, Bₛₜₐᵣₜ=Bₖ, B_{end}=Bₖ₊₁.

Updates made in block 820 move workflow 800 back through blocks 810, 816, and back to 818. In block 818, once a B_{end} is found to be the last local minimum, workflow 800 moves to block 822, in which the greatest peaks are identified and picked. This is performed with all the dominant peaks (DP) recorded from block 816, where each DP contains information of DPₖ={P, Bₛₜₐᵣₜ, B_{end}, h_{P}, h_{B}}, pick Nₚₑₐₖ of the peaks DP that has the greatest height h_{P}. From block 822, precision is improved in block 824 by applying quadratic interpolation, referring to FIG. 7, and using Equations (10)-(11), for each dominant peak picked from block 822, a fitted parabola is computed and is used to predict the location of the parabola's peak P′.

Improvements over current technology is the ability to locate a dominant peak from a group of overlapped ones. The methods and systems described above only identify the dominant peak DPₖ={P, Bₛₜₐᵣₜ, B_{end}, h_{P}, h_{B}}, and treat the nearby peaks within its power range [Bₛₜₐᵣₜ, B_{end}] as minor components. Such advantage also enables the methods and systems described above to avoid reporting the noise as peaks by nature. In contrast, prior works identify all the peaks even when they are overlapping. The systems and methods may include any of the various features of the systems and methods disclosed herein, including one or more of the following statements.

Statement 1. A method may comprise taking one or more measurements with a sensor disposed in a bottom hole assembly, converting the one or more measurements into one or more revolutions-per-minute (RPM) measurements, identifying one or more frequency components of the one or more RPM measurements using a Fast Fourier Transform, identifying one or more peaks of the one or more frequency components, and identifying torsional oscillation based at least in part on the one or more peaks.

Statement 2. The method of statement 1, further comprising applying a low pass filter to the one or more measurements.

Statement 3. The method of any preceding statements 1 or 2, further comprising applying a high pass filter to the one or more measurements.

Statement 4. The method of any preceding statements 1-3, wherein the torsional oscillation is low frequency torsional oscillation or the torsional oscillation is high frequency torsional oscillation.

Statement 5. The method of any preceding statements 1-4, further comprising identifying a local maxima and a local minima from the one or more measurements.

Statement 6. The method of statement 5, further comprising identifying a peak height of the local maxima and a baseline height from a starting point to an ending point.

Statement 7. The method of statement 6, further comprising identifying an average height of the local minima of the starting point and the ending point.

Statement 8. The method of any preceding statements 1-5, further comprising identifying an ascending baseline and a descending baseline in the one or more frequency components.

Statement 9. The method of any preceding statements 1-5 or 8, wherein the sensor is a gyroscope or an accelerometer.

Statement 10. A method may comprise taking one or more signal measurements, identifying one or more frequency components of the one or more signal measurements using a Fast Fourier Transform, and identifying one or more peaks of the one or more frequency components.

Statement 11. The method of statement 10, further comprising identifying a local maxima and a local minima from the one or more signal measurements.

Statement 12. The method of statements 11, further comprising identifying a peak height of the local maxima and a baseline height from a starting point to an ending point.

Statement 13. The method of statement 12, further comprising identifying an average height of the local minima of the starting point and the ending point.

Statement 14. The method of statement 13, further comprising updating the peak height, the starting point, and the ending point if a ratio of the peak height over the average height of the local minima is equal to or less than 0.

Statement 15. The method of any preceding statements 10 or 11, further comprising identifying an ascending baseline and a descending baseline in the one or more frequency components.

Statement 16. The method of any preceding statements 10, 11, or 15, further comprising applying an interpolation to the one or more peaks of the one or more frequency components.

Statement 17. A non-transitory computer-readable tangible medium comprising executable instructions that cause a computer device to take one or more signal measurements, identify one or more frequency components of the one or more signal measurements using a Fast Fourier Transform, and identify one or more peaks of the one or more frequency components.

Statement 18. The non-transitory computer-readable tangible medium of statement 17, wherein the executable instructions further cause the computer device to identify a peak height of a local maxima and a baseline height from a starting point to an ending point.

Statement 19. The non-transitory computer-readable tangible medium of statement 18, wherein the executable instructions further cause the computer device to identify an average height of a local minima of the starting point and the ending point.

Statement 20. The non-transitory computer-readable tangible medium of statement 19, wherein the executable instructions further cause the computer device to update the peak height, the starting point, and the ending point if a ratio of the peak height over the average height of the local minima is equal to or less than 0.

The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method comprising:
taking one or more measurements with a sensor disposed in a bottom hole assembly;
converting the one or more measurements into one or more revolutions-per-minute (RPM) measurements;
identifying one or more frequency components of the one or more RPM measurements using a Fast Fourier Transform;
identifying one or more peaks of the one or more frequency components;
identifying, a peak height and a baseline height from a starting point to an ending point of at least one peak of the one or more peaks; and
identifying torsional oscillation based at least in part on the peak height of the one or more peaks.

2. The method of claim 1, further comprising applying a low pass filter to the one or more measurements.

3. The method of claim 1, further comprising applying a high pass filter to the one or more measurements.

4. The method of claim 1, wherein the torsional oscillation is low frequency torsional oscillation or the torsional oscillation is high frequency torsional oscillation, wherein low frequency torsional oscillation is 0-10 Hz and high frequency torsional oscillation is 40-500 Hz.

5. The method of claim 1, further comprising identifying a local maxima and a local minima from the one or more measurements.

6. (canceled)

7. The method of claim 5, further comprising identifying an average height of the local minima of the starting point and the ending point.

8. The method of claim 1, further comprising identifying an ascending baseline and a descending baseline in the one or more frequency components.

9. The method of claim 1, wherein the sensor is a gyroscope or an accelerometer.

10. A method comprising:
taking one or more signal measurements
identifying one or more frequency components of the one or more signal measurements using a Fast Fourier Transform;
identifying one or more peaks of the one or more frequency components; and
identifying a peak height and a baseline height from a starting point to an ending point of at least one peak of the one or more peaks.

11. The method of claim 10, further comprising identifying a local maxima and a local minima from the one or more signal measurements.

12. The method of claim 11, further comprising identifying a peak height of the local maxima and a baseline height from a starting point to an ending point.

13. The method of claim 12, further comprising identifying an average height of the local minima of the starting point and the ending point.

14. The method of claim 13, further comprising updating the peak height, the starting point, and the ending point if a ratio of the peak height over the average value of the local minima is equal to or less than 0.

15. The method of claim 10, further comprising identifying an ascending baseline and a descending baseline in the one or more frequency components.

16. The method of claim 10, further comprising applying an interpolation to the one or more peaks of the one or more frequency components.

17. A non-transitory computer-readable tangible medium comprising executable instructions that cause a computer device to:
take one or more signal measurements
identify one or more frequency components of the one or more signal measurements using a Fast Fourier Transform;
identify one or more peaks of the one or more frequency components; and
identifying a peak height and a baseline height from a starting point to an ending point of at least one peak of the one or more peaks.

18. The non-transitory computer-readable tangible medium of claim 17, wherein the executable instructions further cause the computer device to identify a peak height of a local maxima and a baseline height from a starting point to an ending point from the one or more signal measurements.

19. The non-transitory computer-readable tangible medium of claim 18, wherein the executable instructions further cause the computer device to identify an average height of a local minima of the starting point and the ending point.

20. The non-transitory computer-readable tangible medium of claim 19, wherein the executable instructions further cause the computer device to update the peak height, the starting point, and the ending point if a ratio of the peak height over the average value of the local minima is equal to or less than 0.
